(19) United States
(12) Patent Application Publication
(10) Pub. No.: US 2006/0185158 A1
(43) Pub. Date: Aug. 24, 2006

(54) Wire insertion system and method

(76) Inventor: Erwin R. Kuhn, Mesa, AZ (US)

Correspondence Address: HARNESS, DICKEY & PIERCE, P.L.C., P.O. BOX 828, BLOOMFIELD HILLS, MI, 48303, US

(21) Appl. No.: 11/062,950

(22) Filed: Feb. 22, 2005

(51) Int. Cl. H01R 43/00; H05K 13/00

(52) U.S. Cl. 29/755; 29/749; 29/854

(57) ABSTRACT

A wire insertion apparatus and method. The apparatus includes a frame that supports X-axis and Y-axis linear actuators driven by corresponding DC motors. The Y-axis linear actuator supports a laser that generates a laser beam to illuminate a specific wire cavity on an electrical connector body. The connector body is held between movable jaws supported from a holder subassembly from the frame. The system may be used with a database program that allows a user to select a specific conductor or wire cavity of a specific connector. Upon this selection, a computer system generates suitable X-axis and Y-axis position information to enable the X-axis and Y-axis motors to position the laser as needed to illuminate the specific wire cavity into which the conductor needs to be inserted. A wire may then be quickly and easily manually inserted by an assembly worker into the illuminated wire cavity.

### FIELD OF THE INVENTION

The present invention relates to wire insertion systems for assisting a user in assembling wires to an electrical connector and, more particularly, to a portable system that illuminates specific wire cavities of a connector to precisely identify for a user the exact wire cavity that a particular wire is to be inserted into during construction of a wiring harness.

### BACKGROUND OF THE INVENTION

Assembly of individual wires (i.e., electrical conductors) into the cavities of an electrical connector body is an extremely labor intensive process. The assembly of wires to the connector body is complicated by the fact that many connector bodies require dozens, or even 100 or more, individual wires to be assembled to the connector body. The cavities in the connector body are typically arranged in rows and columns, regardless if the connector body is round, rectangular or square in shape. Since the cavities are typically arranged in very compact fashion, there is insufficient room to print a cavity number adjacent each cavity. Thus, for an individual assembling dozens or hundreds of individual wires to a connector body, visually determining a particular wire cavity requires significant concentration and patience, especially in view of the limited numbering associated with the cavities on the connector body. It is very easy for an individual to place a particular wire in the wrong wire cavity during assembly. If this occurs, the incorrectly located wire will be detected during subsequent testing, thus necessitating disassembly of at least two wires and then reconnecting the wires in the correct cavities. This can be a time consuming and expensive process. The rubber grommet in the connector body is often damaged during this rework operation, this requiring replacement of the connector and reinserting all wires in the proper location.

Previously developed systems for assisting in constructing wiring harness have traditionally proven to be large and non-portable. Thus, such systems cannot be readily used at a workbench or moved about in an assembly facility so as to be made available close to inventories of wires and connectors. To the contrary, with large, fixed location wiring assembly systems, all of the wires used to make a wiring harness, as well as the connectors, must be brought to the machine. It would be highly desirable for a wire assembly apparatus to be provided that is portable and that can be used at various locations within an assembly facility, and moved about as needed.

### SUMMARY OF THE INVENTION

The present invention is directed to a wire assembly apparatus and method for assisting an individual in assembling a wiring harness. More particularly, the apparatus and method assists an individual in precisely locating specific wire cavities on an electrical connector body during assembly of a wiring harness. The system and method eliminates the likelihood of an individual securing a particular wire in an incorrect cavity of the connector body. A particular advantage of the apparatus is that it is compact, lightweight, and thus portable, and can be moved about in an assembly facility as needed to improve productivity.

In one preferred form the apparatus includes a frame that supports a positioning system and a holder assembly. The positioning system supports a laser and can be interfaced with an external computer system. The positioning system receives X and Y coordinate position information from the external computer system and precisely moves the laser in X and Y directions to locate it over a specific wire cavity in an electrical connector body that is being held by the holder assembly. The laser generates a light beam of sufficiently small diameter that illuminates a single wire cavity in the connector body. This enables a technician to quickly identify a specific cavity into which a specific wire is to be inserted when assembling a plurality of wires to the electrical connector to form a wiring harness. It also eliminates the possibility of error that would exist if the technician was required to visually count and identify specific wire cavities where each wire needs to be inserted.

In one preferred form the apparatus includes a pair of jaws that are able to grasp electrical connector bodies of varying sizes and shapes. A mechanism is further provided for enabling a user to quickly and easily open and close the jaws once a connector body is placed between the jaws. The laser is sufficiently compact so that a user can easily view the surface of the connector body being illuminated by the laser and clearly see which wire cavity is being illuminated by the laser beam.

The features, functions, and advantages can be achieved independently in various embodiments of the present inventions or may be combined in yet other embodiments.

### BRIEF DESCRIPTION OF THE DRAWINGS

The present invention will become more fully understood from the detailed description and the accompanying drawings, wherein:

FIG. 1 is a perspective view of a system in accordance with a preferred embodiment of the present invention shown coupled with a computer system

FIG. 2 is an exploded perspective view of a portion of the system illustrating the components that cooperate in holding a connector stationary during an assembly process;

FIG. 3 is a plan view of the jaws of the system and the actuating assembly with the jaws positioned in a closed position;

FIG. 4 is a plan view of the assembly of FIG. 3 but with the jaws in the fully opened position;

FIG. 5 is a perspective view of one of the linear bearings of the system fully assembled;

FIG. 6 is an enlarged perspective view of the other linear bearing assembly of the system fully assembled;

FIG. 7 is an exploded perspective view of the portion of the system that supports the X-axis and Y-axis motors;

FIG. 7a is an enlarged perspective view of a back end of the mounting block shown in FIG. 7;

FIG. 8 is an exploded perspective view of the mounting structure used to support the Y-axis motor and actuator;

FIG. 8a is a partial side cross sectional view of the end of the actuator member secured to the X-axis motor/actuator support structure; and

FIG. 9 is a simplified diagram of a computer screen illustrating the fields that a suitable database program may incorporate, for use with the system of the present invention.

### DETAILED DESCRIPTION OF THE PREFERRED EMBODIMENTS

The following description of the preferred embodiment(s) is merely exemplary in nature and is in no way intended to limit the invention, its application, or uses.

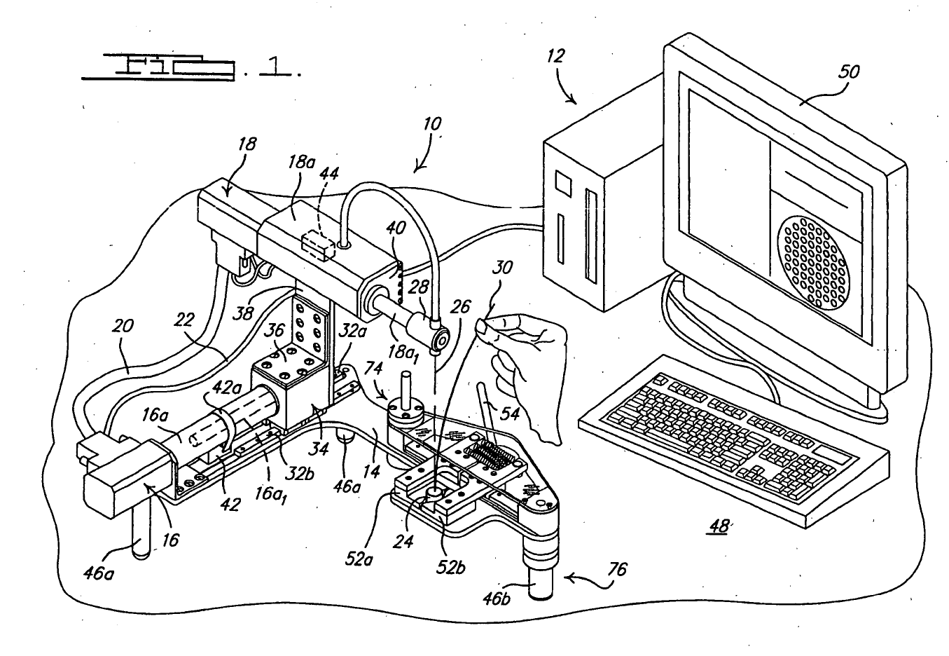

Referring to FIG. 1, there is shown a portable wire insertion system 10 in accordance with a preferred embodiment of the present invention. The apparatus 10 is typically used in conjunction with a computer system 12 which supplies position information to the system 10 that enables the system 10 to illuminate a specific wire cavity in a specific electrical connector. The system 10 generally includes a frame 14 from which is supported an X-axis motor 16 and a Y-axis motor 18. Each of the X axis and Y axis motors 16 and 18 has its output shaft coupled to an associated linear actuator 16a and 18a. Each linear actuator 16a and 18a has a linearly movable member 16a₁ and 18a₁, respectively, that extends and retracts within a sleeve in accordance with electrical signals supplied via a wiring harness 20 coupled to the actuators 16a and 18a. The motors 16 and 18 are commercially available from Animatics Corp., of Santa Clara, Calif., and form DC “smart” motors. The linear actuators are commercially available from Ultramotion, LLC, of Mattituck, N.Y.

The wiring harness 20 is in communication via an interface cable 22 with the computer system 12. In general, any suitable database program for maintaining X and Y positional information relating to wire cavities for specific connectors may be implemented on the computer system 12. More preferably, additional information such as the gauge of specific wires to be inserted at specific connector cavities is included in the program running on the computer system 12. Thus, the user selects from the database program a specific one of a plurality of different types of connectors having different wire cavity configurations. The database program provides information to the user pertaining to the specific type of wire that is to be inserted into each wire cavity of the selected connector, which in FIG. 1 is illustrated in simplified form as a circular connector 24. The system 10 uses a laser beam 26 projected from a laser 28 mounted on the member 18a to illuminate a single wire cavity of the connector 24. The user can then easily visually identify the wire cavity and subsequently insert a specific wire 30 into the illuminated wire cavity. This dramatically reduces the possibility of inserting the wire 30 into the wrong wire cavity which could necessitate time consuming and expensive disassembly and reassembly of the connector 24. This is especially so with connectors incorporating a large number of wires, such as 50 to 200 wires, which is common in many applications, and particularly in wiring harnesses used in aerospace applications and with modern commercial and military aircraft and other complex mobile platforms. It will be appreciated, then, that the system 10 significantly reduces the time in which a wiring harness can be formed, as well as significantly reducing the possibility of a technician installing a specific wire into an incorrect wire cavity of the connector body.

With further reference to FIG. 1, the system 10 includes a pair of linear guide rails 32a, 32b on which is mounted an X-axis support block assembly 34. The X-axis support block assembly 34 is free to move in an X direction towards and away from the X-axis motor 16 in accordance with linear movement of the X-axis actuator member 16a₁. The Y-axis motor 18 is supported from the X-axis block assembly 34 via an angled support member 36, a support member 38 and a support bracket 40. The laser 28, which in one preferred form comprises a Class II laser, is supported on the terminal end of member 18a₁. The laser beam 26 is sufficiently small in diameter to illuminate substantially only a single wire cavity in the body of the connector 24. X and Y position information fed to the motors 16 and 18 thus enables the laser 28 to be precisely moved in X and Y directions to illuminate a specific wire cavity. Magnetic sensor switches 42 and 44 fixed securely to their respective mounting structures sense moving magnetic components (not shown) on the members 16a₁ and 18a₁, respectively, and are used to align the laser beam 26 at predetermined X and Y “null” positions at the center of any given connector during initial setup of the system 10. Once the laser beam 26 is positioned at the X and Y null positions and, then “+” and “−” X and Y positional information transmitted from the computer system 12 is used by the motors 16 and 18 to move the members 16a₁ and 18a₁ by predetermined designated linear distances relative to the null positions. For convenience, the frame 14 may be supported by a plurality of legs 46a and 46b above a table 48 or other work surface. The computer system 12 is preferably positioned adjacent the system 10. A user viewing a computer screen 50 can select a particular wire cavity and a particular connector from a suitable database program. The program also preferably provides an illustration of the connector wire cavity pattern, as well as specific information on each wire to be inserted into each wire cavity of the selected connector. The system 12 generates position information that causes the laser 28 to point its laser beam 26 at the designated wire cavity in the connector 24. If the computer screen 50 is in close proximity to the system 10, then the user can work between the computer system 12 and the system 10 rapidly and efficiently.

With further reference to FIG. 1, the system 10 includes a pair of opposing movable jaws 52a and 52b. A lever 54, manually engageable by a user, is used to open and close the jaws 52a, 54b to hold the connector 24. While the connector 24 is shown as a circular connector, virtually any other shape of connector, such as rectangular, hexagonal, or octagonal, can also be accommodated. The jaws 52a, 52b are shaped to provide an opening that is sufficiently large and further shaped so as to hold a variety of differently shaped connector bodies.

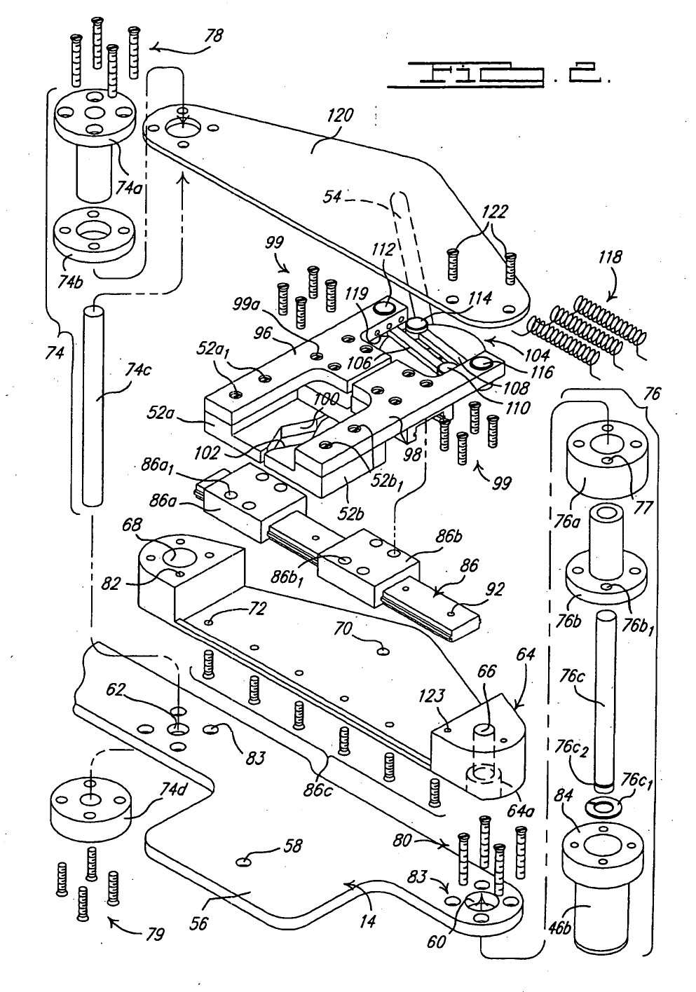

Referring to FIG. 2, an exploded perspective view of the area of the system 10 that supports connector 24 is shown. Frame portion 14 includes a support area 56 having an opening 58, an opening 60, and an opening 62. Opening 58 is preferably just slightly larger in diameter than the laser beam 26 and is utilized to set the null position. A mounting member 64 having bores 66 and 68 is positioned over the frame 14. The mounting member 64 also includes an opening 70 and a plurality of openings 72. Linear bearings 74 and 76 are disposed in the openings 68 and 66, respectively, and allow the mounting member 64 to be moved freely approximately one and one half inch vertically relative to the frame 14. Guide Pin 74c is securely pressfit to bushing 74d and is secured to frame 14 with fasteners 79 through holes 83. Guide pin 76c is securely pressfit to mounting member 64 in hole 66. Linear bearing 74 is secured to mounting member 64 via fastening members 78. Fasteners 78 extend through holes in bearing 74a, spacer 74b, cover 120 and thread into threaded holes 82 in the mounting member 64. Linear bearing 76 is secured to the frame 14 via fastening members 80. Fasteners 80 extend through holes 83 and into holes 77 in a bushing 76a, through holes 76b₁ in member 76b and into threaded holes 84 in hollow leg 46. The mounting member 64 includes a counter bore 64a into which portion 76b₂ extends when the linear bearing 76 is fully assembled to the mounting member 64. A retaining clip 76c₁ is secured to a groove 76c₂ on the guide pin 76. The clip 76c₁ serves to prevent the mounting member 64 from being lifted completely off of the frame because of abutting engagement with a lower surface of spacer 76b once fully assembled.

With further reference to FIG. 2, guide member 86 is secured via threaded fasteners 86c that extend into openings 72. Guide member 86 incorporates a plurality of openings 92 to facilitate the securing. Slidably secured to the guide member 86 is a pair of bearing blocks 86a and 86b. Bearing blocks 86a and 86b are secured to the holder elements 96 and 98 via threaded fasteners 99 that extend through holes 99a in the holder elements 96, 98 and into threaded blind holes 86a₁ and 86b₁ in the bearing blocks 86a and 86b. It will be appreciated that, however, the bearing blocks 86a and 86b will, during actual assembly, be slid onto the guide members 86 from one or the other of its ends, before being secured to the holder elements 96 and 98. The bearing blocks 86a, 86b and guide member 86 are commercially available as a set from Speciality Motion, Inc., of Yorba Linda, Calif., or from THK Co., Ltd., of Chicago, Ill.

Clamping jaw 52b is secured to the holder element 98 via threaded fasteners 52b₁ while clamping jaw 52a is secured to holder element 96 via threaded fasteners 52a₁. Each of jaws 52a and 52b include cut-out areas 100 and 102 that cooperatively form a preferably diamond shaped opening. However, the precise shape of the opening may be varied as needed. The opening formed by cut-outs 100 and 102, however, is sufficient to hold a wide variety of connectors of circular, square, rectangular, or other shapes, and having varying dimensions.

With further reference to FIG. 2, an actuator lever assembly 104 including actuator lever 54 is coupled to the holder elements 96 and 98 via connecting elements 106 and 108. Mounting member 64, holder elements 96, 98 and actuator lever assembly 104 essentially form a holder assembly that is movable vertically along the linear bearings 76, 74 to allow jaws 52a and 52b to better grip connector bodies having a varying height.

Connecting element 106 is coupled between connecting pins 110 and 112, while element 108 is coupled between pins 114 and 116. One or more biasing elements 118 are coupled to the holder elements 96 and 98 at holes 119 in each holder element to bias the holder elements towards one another such that jaws 52a and 52b are normally biased to the closed position. Cover member 120 is secured to portions of the linear bearing 74 via fasteners 78, as well as to the mounting member 64 by threaded fasteners 122 that extend into threaded blind holes 123 in the mounting member 64.

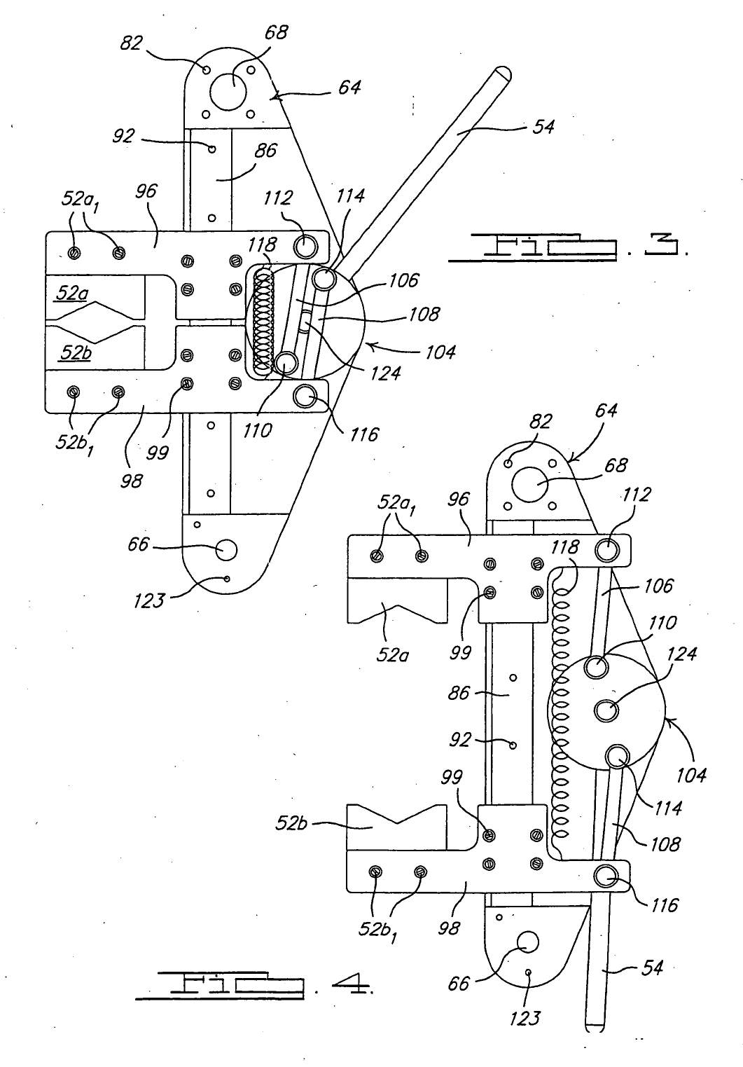

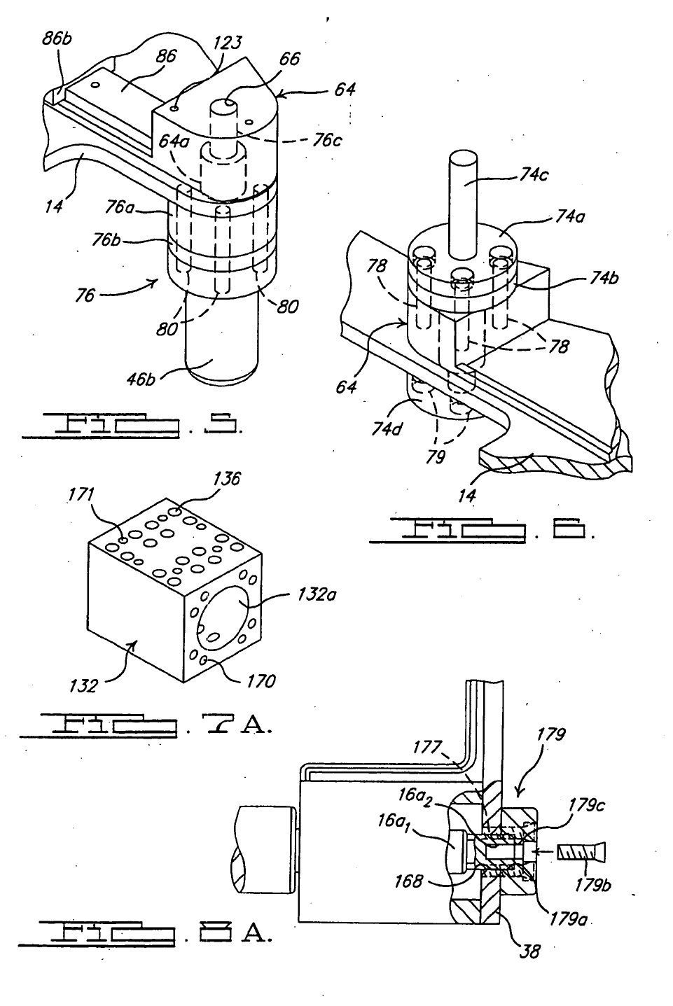

Referring briefly to FIGS. 3 and 4, the holder elements 96 can be seen in their fully opened and fully closed positions. The actuating assembly 104 is supported for rotational movement by a fastening element 124 that extends into threaded opening 70 in the mounting member 64 (FIG. 2).

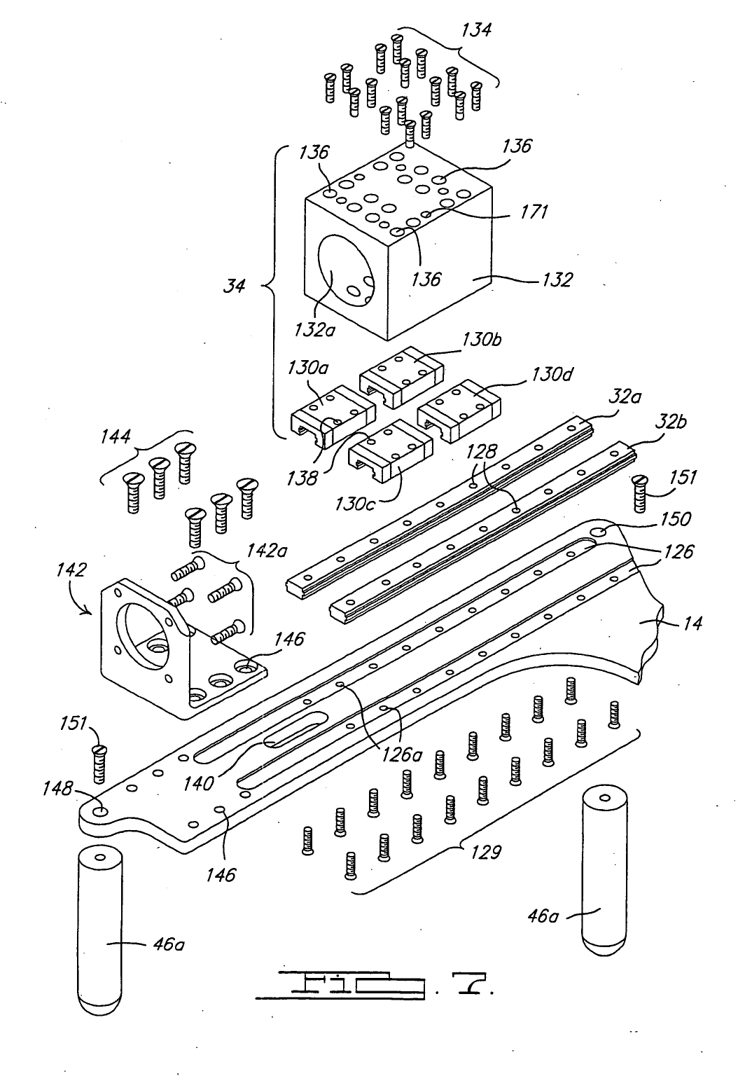

Referring to FIG. 5, the linear bearing 76 is shown fully assembled in enlarged perspective fashion. Leg 46b forms an integral portion of linear bearing 76. Mounting member 64 is free to move vertically relative to frame 14 about 1.5 inches (38.1 mm). As shown in FIGS. 2 and 5, bushings 76a, 76b and leg 46b are effectively clamped to frame 14. Guide pin 76c is pressfit into hole 66 to guide vertical movement of the mounting member 64. FIG. 6 illustrates, in enlarged perspective fashion, the securing of the linear bearing 74 to the frame 14 and mounting member 64. Bushings 74a and 74b (shown in FIG. 2 also) provide a guide for rod 74c which is pressfit to bushing 74d. Bushing 74d is held to frame 14 via fasteners 79.

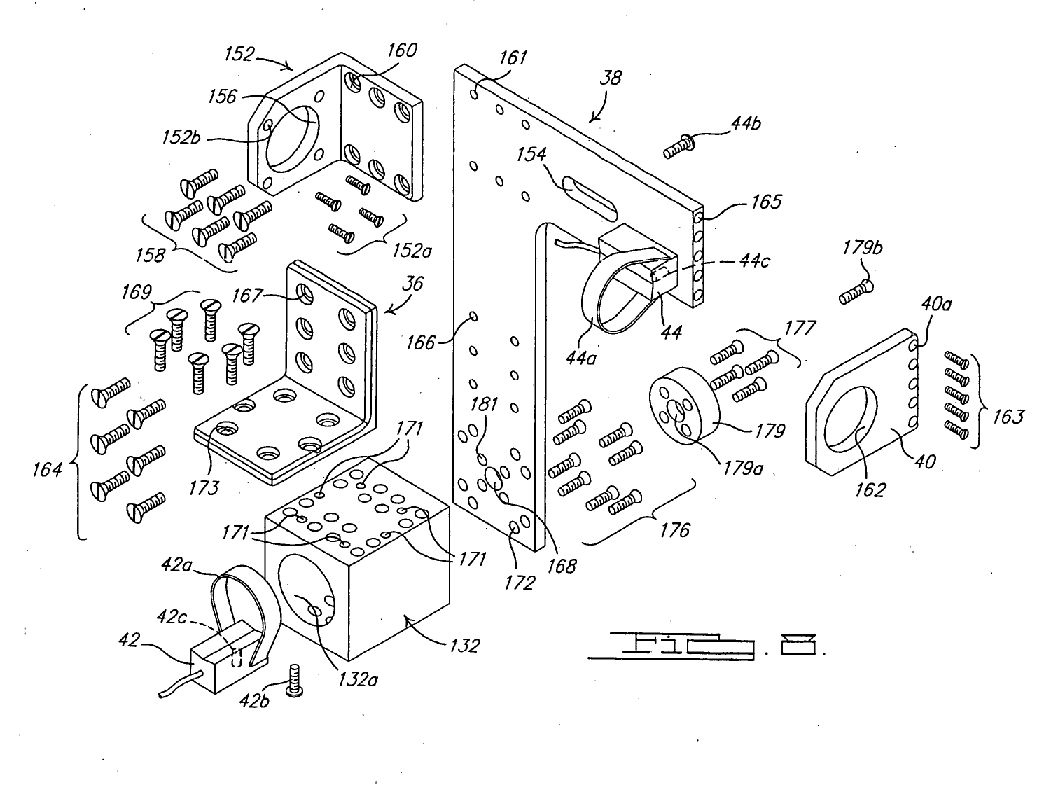

Referring to FIG. 7, the portion of the frame 14 that supports the X-axis motor 16 and the mounting block assembly 34 is shown. The frame 14 includes a pair of parallel recessed slots 126 within which the pair of linear guide rails 32a and 32b are secured via threaded fasteners 129. Fasteners 129 extend through holes 126a and into threaded holes 128 in the rails 32.

Bearing blocks 130a-130d are slidably coupled to respective ones of the guide rails 32 so that blocks 130a and 130b are positioned adjacent one another on guide rail 32a and blocks 130c and 130d are positioned adjacent one another on the other guide rail 32b. The bearing blocks 130 and guide rails 32 are commercially available as sets from Speciality Motion, Inc., as well as from THK Co., Ltd. Support block 132 has a bore 132a and is secured to the blocks 130a-130d via a plurality of threaded fasteners 134. Fasteners 134 extend through 16 corresponding bores 136 in the block 132 and into blind threaded holes 138 in each of the blocks 130a-130d.

With further reference to FIG. 7, the frame 14 also includes a slot 140 used to access a tightening fastener for magnetic sensor switch 42 for fixing the null adjustment. An L-shaped support bracket 142 secures to the X-axis motor 16 with four threaded fastening elements 142a. L-shaped support bracket 142 is secured via threaded fasteners 144 that extend into openings 146. Openings 148 and 150 allow for fastening members 151 to be used to secure legs 46a to the frame 14.

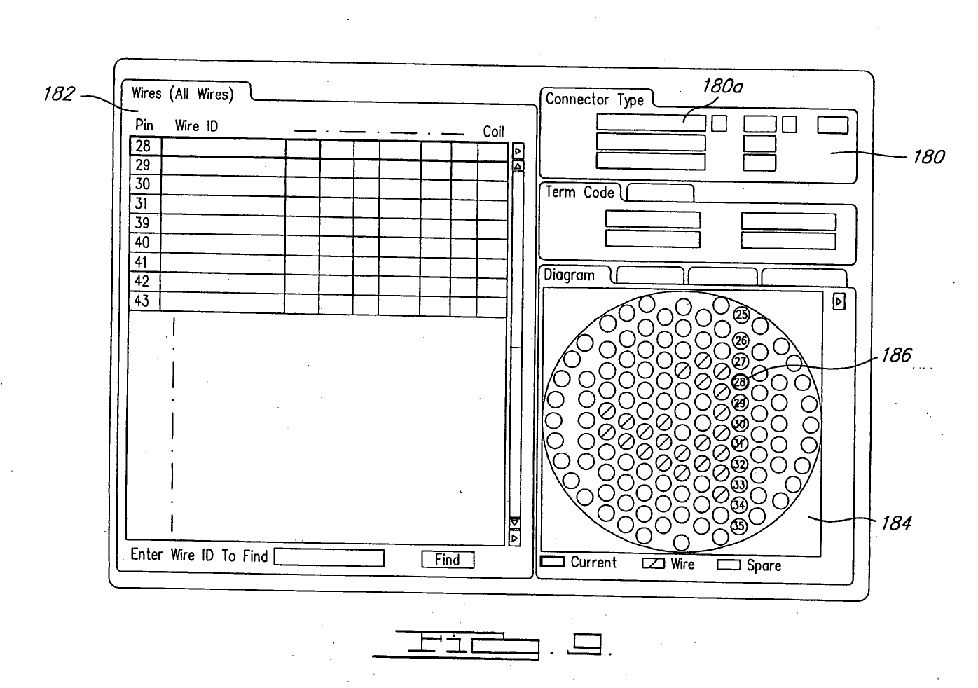

Referring to FIG. 8, Y-axis motor support bracket 38 is shown in greater detail together with an L-shaped support element 152. Support bracket 38 includes a slot 154 used to access a tightening fastener 44b that engages a threaded hole 44c in sensor switch 44. A metallic clamp 44a is arranged over a portion of the Y-axis actuator 18a to sense linear movement of the internal member 18a₁. Magnetic sensor switch 42 similarly includes a threaded opening 42c for receiving a threaded fastener 42b that extends through slot 140 (FIG. 7) to fix the position of sensor 42. Metallic clamp 42a is placed around a portion of the X-axis linear actuator 16a to sense movement of internal member 16a₁ for magnetic sensor switch 44 for fixing the null adjustment. L-shaped bracket 152 includes an opening 156 that secures to the Y-axis motor 18 with four threaded fastening elements 152a extending through four openings 152b. Fastening elements 158 secure the L-shaped bracket 152 to the support bracket 38 via openings 160 and threaded openings 161. The support bracket 40 also includes a generally circular opening 162 that is longitudinally aligned with opening 156 to further support the neck portion of the Y-axis linear actuator 18a. Support bracket 40 includes a plurality of five holes 40a through which threaded fasteners 163 extend. Fasteners 163 engage in five blind threaded holes 165 in bracket 38.

Support bracket 36 is also secured to the support bracket 38 via a plurality of fastening elements 164 that extend through holes 167 in the bracket 36 and into threaded holes 166 in the support bracket 38. Threaded fasteners 169 secure the support bracket 36 to the block 132 and extend through six holes 173 in the bracket 36 and into six threaded holes 171 in the block 132.

With brief reference to FIGS. 7a and 8, the block 132 includes a plurality of eight threaded blind holes 170 which align with eight openings 172 in the bracket 38. Bore 168 aligns with bore 132a of block 132. Eight fastening elements 176 extend through openings 172 to engage openings in blind holes 170, respectively, to thus secure the block 132 to the support bracket 38. Threaded fasteners 177 secure bushing 179 to the support member 38 by engaging threaded holes 181. Referring to FIG. 8a, the X-axis actuator member 16a₁ extends through bore 132a, through hole 168 and into a counterbore 179a in bushing 179. It is secured by a fastener 179b extending through a hole 179c that opens into the counterbore 179a. The fastener engages a blind threaded hole 16a₂ in the end of the member 16a₁.

Referring to FIG. 9, a simplified illustration of a display of a database program for use with computer system 12 is shown. The program presents a field 180 for inputting, into one or more subfields 180a, information concerning a specific connector or wiring harness. On this information, specific wire information is presented in field 182 along with the specific wire cavity of the connector with which the wire is associated. In field 184, a diagram of the wire cavities of the selected connector is shown and a specific wire cavity corresponding to the selected wire may be illuminated or otherwise highlighted as indicated by the illumination marks around one of the specific wire cavities 186 shown in field 184. Thus, the user may select a specific pin or wire from field 182 and the corresponding wire cavity of the connector body will be highlighted in field 184. Concurrently, the laser 28 illuminates the same wire cavity on the connector body 24 that is being held between the jaws 52a and 52b (FIG. 1). Thus, the user can quickly and easily select the proper wire from among a larger plurality of wires available at the work area, and insert the selected wire into the proper wire cavity in the connector body 24 while the cavity is being illuminated by the laser beam 26 (FIG. 1). Again, other database-type arrangements may be implemented, but it is anticipated that a database program that allows a user to select a particular wire cavity, and that automatically provides an output enabling the laser 28 to illuminate the selected cavity, will be the minimum operational parameters that is required for implementing the system 10.

The system 10 thus forms a means by which a user can reliably, quickly and easily identify the proper cavity into which a wire needs to be inserted during the fabrication of a wiring harness. The system 10 dramatically reduces the possibility of inserting a given wire into an incorrect wire cavity in a connector body. The system 10 also increases the throughput of wire harness fabrication by enabling a user to more quickly identify specific cavities into which specific wires need to be inserted during the wiring harness manufacturing process. The system 10 thus eliminates the need for the user to visually count cavities on the connector body before being able to identify a specific cavity into which a wire needs to be inserted, since the laser beam generated by the system 10 quickly illuminates the selected cavity once a given wire is selected from the database program being used with the system.

While various preferred embodiments have been described, those skilled in the art will recognize modifications or variations which might be made without departing from the inventive concept. The examples illustrate the invention and are not intended to limit it. Therefore, the description and claims should be interpreted liberally with only such limitation as is necessary in view of the pertinent prior art.

What is claimed is:

1. An apparatus for assisting in the placement of wires in wire cavities of an electrical connector, the apparatus comprising:
a frame;
a holder supported by said frame for releasably holding an electrical connector in a desired orientation;
a laser for generating a laser beam sufficiently small in diameter to irradiate a single wire cavity in said connector;
a positioning subsystem operably associated said laser, and responsive to electrical signals from an external computer, for positioning said laser at a desired X-Y coordinate point on a surface of said connector, wherein said X-Y coordinate point corresponds to a specific wire cavity in said connector into which a specific one of said wires is to be inserted.

2. The apparatus of claim 1, wherein said positioning system includes:
an X-axis motor system for moving an X-axis support element linearly along an X-axis path of travel;
a Y-axis motor system for moving a Y-axis support element linearly along a Y-axis path of travel; and
an electrical cable for coupling each of said X-axis and Y-axis motor systems with an interface port of said external computer.

3. The apparatus of claim 1, wherein said holder comprises a pair of jaws pivotally supported on said frame and at least one spring for biasing said jaws toward each other.

4. The apparatus of claim 1, wherein said holder further comprises a manually engageable member operably associated with at least one of said jaws for manually urging at least one of said jaws towards the other.

5. The apparatus of claim 3, wherein said holder comprises at least one linear bearing for enabling a spacing of said holder, relative to said frame, to be adjustably controlled.

6. An apparatus for assisting in the placement of wires in an electrical connector, the apparatus comprising:
a frame;
a holder supported by said frame for releasably holding an electrical connector in a desired orientation;
a laser for generating a laser beam sufficiently small in diameter to irradiate a single wire cavity in said electrical connector, thus optically indicating to a user a precise wire hole into which a wire is to be manually inserted;
a computer system for generating X and Y coordinate information corresponding to a specific desired wire cavity in said electrical connector;
a positioning subsystem operably associated said laser, and responsive to said X and Y coordinate information generated by said computer system, for positioning said laser at a desired X-Y coordinate point on a surface of said electrical connector, wherein said X-Y coordinate point corresponds to a desired wire cavity in said electrical connector into which a specific one of said wires is to be inserted.

7. The apparatus of claim 6, wherein said positioning system comprises:
an X-axis motor system for moving an X-axis support element linearly along an X-axis path of travel;
a Y-axis motor system for moving a Y-axis support element linearly along a Y-axis path of travel; and
an electrical cable for coupling each of said X-axis and Y-axis motor systems with said computer system.

8. The apparatus of claim 6, wherein said holder system comprises a pair of spring biased jaws supported for sliding movement towards and away from one another; and
a manually moveable member operably associated with said jaws for controlling positioning of said jaws.

9. The apparatus of claim 8, wherein said jaws are supported on a support member to enable adjustable vertical positioning of said jaws relative to said frame.

10. The apparatus of claim 6, wherein said apparatus is sufficiently compact and light in weight to be portable.

11. The apparatus of claim 8, wherein said jaws accommodate at least one of circular, square and rectangular shaped electrical connectors.

12. The apparatus of claim 6, wherein said holder comprises a support member supported by a plurality of linear bearings, said linear bearings enabling said support member and said jaws to be vertically positioned relative to said frame.

13. The apparatus of claim 6, wherein said frame comprises a plurality of feet for supporting said frame above a work surface on which said apparatus is placed.

14. The apparatus of claim 6, wherein said holder comprises:
a pair of slidably mounted jaws;
a spring for biasing said jaws towards one another;
a lever operably associated with at least one of said jaws, and manually engageable with a finger of a user, for urging said jaws away from one another to permit insertion of said electrical connector between said jaws.

15. The apparatus of claim 14, wherein said holder further comprises a support member supported on a plurality of linear bearings for enabling adjustable positioning of a height of said jaws relative to said frame.

16. An apparatus for assisting in the placement of wire cavities in an electrical connector body, the apparatus comprising:
a frame;
a holder supported by said frame for releasably holding an electrical connector in a desired orientation, said holder further including:
a pair of jaws for grasping said electrical connector;
a cam actuated release member operably associated with at least one of said jaws for enabling a user to move said jaws into engaged and disengaged positions relative to an electrical connector positioned between said jaws; and
at least one spring for biasing said jaws towards one another;
a laser for generating a laser beam sufficiently small in diameter to irradiate a single wire cavity in said electrical connector body, thus optically indicating to a user a precise wire cavity into which a wire is to be manually inserted;
a computer system for generating X and Y coordinate information corresponding to a specific desired wire cavity in said electrical connector;
a positioning subsystem operably associated said laser, and responsive to said X and Y coordinate information generated by said computer system, for positioning said laser at a desired X-Y coordinate point on a planar surface of said electrical connector, wherein said X-Y coordinate point corresponds to a desired wire cavity in said electrical connector into which a specific one of said wires is to be inserted, said positioning subsystem including:
an X-axis motor and a linearly driven X-axis member movable along an X-axis by said X-axis motor;
a Y-axis motor and a linearly driven Y-axis member movable along a Y-axis by said Y-axis motor; and
wherein said laser is supported on one of said linearly driven X-axis and Y-axis members.

17. The apparatus of claim 16, wherein said holder further comprises a mounting member supported from said frame to enable vertical positioning of said platform, and thus said jaws, relative to said frame.

18. The apparatus of claim 17, wherein said holder further comprises a plurality of linear bearings for facilitating vertical positioning of said platform.

19. The apparatus of claim 16, wherein said laser comprises a class II laser.

20. The apparatus of claim 16, wherein said X-axis motor and said Y-axis motor each comprises servo motors.
